(19) United States
(12) Patent Application Publication
(10) Pub. No.: US 2025/0376605 A1
(43) Pub. Date: Dec. 11, 2025

(54) THERMALLY CONDUCTIVE ADHESIVE COMPOSITION AND PRODUCING METHOD THEREOF, THERMALLY CONDUCTIVE FILM ADHESIVE, AND SEMICONDUCTOR PACKAGE USING THERMALLY CONDUCTIVE FILM ADHESIVE AND PRODUCING METHOD THEREOF

(71) Applicant: FURUKAWA ELECTRIC CO., LTD., Tokyo (JP)

(72) Inventor: Minoru MORITA, Tokyo (JP)

(73) Assignee: FURUKAWA ELECTRIC CO., LTD., Tokyo (JP)

(21) Appl. No.: 19/311,471

(22) Filed: Aug. 27, 2025

Related U.S. Application Data
(63) Continuation of application No. PCT/JP2024/005479, filed on Feb. 16, 2024.

(30) Foreign Application Priority Data
Feb. 28, 2023 (JP) 2023-029805

(51) Int. Cl. C09J 7/35; C09C 3/04; C09J 5/06; C09J 7/10; C09J 9/00; C09J 11/04; C09K 5/14; H01L 21/683; H01L 21/78; H01L 23/00

(52) U.S. Cl. CPC C09J 7/35; C09C 3/041; C09J 5/06; C09J 7/10; C09J 9/00; C09J 11/04; C09K 5/14; H01L 24/29; C01P 2006/32; C09J 2203/326; C09J 2301/304; C09J 2301/408; C09J 2301/416; H01L 21/6836; H01L 21/78; H01L 24/32; H01L 24/83; H01L 2224/2929; H01L 2224/29387; H01L 2224/32145; H01L 2224/32225; H01L 2224/83203

(57) ABSTRACT

Provided are a thermally conductive adhesive composition including an epoxy resin (A), an epoxy resin curing agent (B), a polymer component (C), and a nitride ceramic filler (D), wherein the nitride ceramic filler (D) satisfies the following conditions: (1) an image analysis average particle diameter is 0.1 to 2.5 μm; (2) an image analysis circularity is 0.7 or more; and (3) an image analysis maximum particle diameter is 10.0 μm or less, and wherein a proportion of the nitride ceramic filler (D) in a total content of the epoxy resin (A), the epoxy resin curing agent (B), the polymer component (C), and the nitride ceramic filler (D) is 25 to 65% by volume, as well as a thermally conductive film adhesive and a semiconductor package, and a producing method thereof.

### CROSS-REFERENCE TO RELATED APPLICATIONS

This application is a Continuation of PCT International Application No. PCT/JP2024/005479 filed on Feb. 16, 2024, which claims priority under 35 U.S.C. § 119 (a) to Japanese Patent Application No. 2023-029805 filed in Japan on Feb. 28, 2023. Each of the above applications is hereby expressly incorporated by reference, in its entirety, into the present application.

### FIELD OF THE INVENTION

The present invention relates to a thermally conductive adhesive composition and a producing method thereof, a thermally conductive film adhesive as well as a semiconductor package using the thermally conductive film adhesive and a producing method thereof.

### BACKGROUND OF THE INVENTION

With advanced downsizing, high-functionality, and multi-functionality of electronic devices in recent years, high-functionality and multi-functionality have also been advanced in semiconductor packages mounted in the electronic devices, and miniaturization in the wiring rule of the semiconductor wafer has been advanced. Stacked MCPs (Multi Chip Package) in which semiconductor chips are multistacked have been widely spread along with high-functionality and multi-functionality. Such stacked MCPs are mounted on memory packages for mobile phones, portable audio devices, and the like. Further, along with multi-functionality of mobile phones and the like, high densification and high integration of the package have also been advanced. Along with such advance, multistacking of the semiconductor chips has been further advanced.

A film adhesive (die attach film) is used for bonding a circuit board and a semiconductor chip or bonding semiconductor chips (what is called die attach) in a process of producing such a memory package. Along with multistacking of the chips, reduction in thickness of the die attach film has been demanded. Also, miniaturization in the wiring rule of the wafer has been advanced in recent years, and, as a result, heat is more likely to be generated on the surface of the semiconductor element. Therefore, in order to easily dissipate heat to the outside of the package, a thermally conductive filler (inorganic filler) is blended in the die attach film to realize high thermal conductivity.

A thin thermally conductive die attach film is designed as a film adhesive highly filled with a thermally conductive filler having a small particle diameter. However, when the filler particle diameter is small, a specific surface area becomes large, and thus interaction between fillers becomes significant. Consequently, aggregation of the fillers tends to occur when the fillers are mixed with a resin during production of a die attach film. As a result, aggregates are easily scattered on the surface of the thin thermally conductive die attach film to be obtained. In addition, the thermally conductive filler having a small particle diameter tends to lower the fluidity of the die attach film and increase the melt viscosity of the die attach film. Thus, the thin thermally conductive die attach film highly filled with a thermally conductive filler having a small particle diameter tends to entrap voids into the back surface of the semiconductor chip or the circuit board, which is an adherend. Moreover, the film cannot be sufficiently embedded in the unevenness of the circuit board. Therefore, problems such as reduction in adhesive strength and reduction in heat dissipation performance tend to occur.

Regarding a thermally conductive die attach film, for example, Patent Literature 1 describes an adhesive composition containing an epoxy resin (A), an epoxy resin curing agent (B), a polymer component (C), and an inorganic filler (D) in specific amounts, wherein an average particle diameter (d50) of the inorganic filler (D) is from 0.1 to 3.5 μm, and a ratio of a particle diameter (d90) at a cumulative distribution frequency of 90% to the average particle diameter (d50) is 5.0 or less. According to the technology described in Patent Literature 1, by preparing a film adhesive using this adhesive composition, generation of voids after a die attach step can be suppressed even in the form of a thin film, and a film adhesive having an excellent strength of adhesion to an adherend and excellent thermal conductivity can be obtained.

In addition, Patent Literature 2 describes a heat-dissipating film adhesive containing two or more kinds of thermally conductive fillers having different Mohs hardness and having a blade wear amount of 50 μm/m or less in a dicing step.

### CITATION LIST

### Patent Literature

Patent Literature 1: WO 2021/033368
Patent Literature 2: JP-A-2019-21829 (“JP-A” means an unexamined published Japanese patent application)

### SUMMARY OF THE INVENTION

### Technical Problem

In order to enhance the thermal conductivity of a film adhesive, nitride ceramics (ceramics containing a nitrogen element) such as aluminum nitride having high thermal conductivity are regarded as promising filler materials. As a fine filler material of the nitride ceramic, various commercially available products are obtainable. However, in order to further improve the performance of the resulting film adhesive, a technique for effectively suppressing the aggregation of fillers and the increase in the melt viscosity of the film adhesive described above is required.

The present invention has been made in view of the above problems of the prior art. It is an object of the present invention to provide a thermally conductive film adhesive using a nitride ceramic filler material (nitride ceramic filler) such that in the thermally conductive film adhesive, aggregation of fillers can be suppressed and an increase in the melt viscosity of the film adhesive can also be suppressed while the nitride ceramic filler has a smaller particle diameter; a thermally conductive adhesive composition suitable for formation of the thermally conductive film adhesive, and a producing method thereof.

In addition, the present invention provides a semiconductor package using the thermally conductive film adhesive having the above excellent characteristics and a producing method thereof.

### Solution to Problem

As a result of intensive studies to solve the above problems, the present inventors have found that when a nitride ceramic filler is subjected to a pulverization and deaggregation treatment to form a filler having a smaller particle diameter, the circularity of the filler is increased, the interaction between filler particles is weakened, aggregation is suppressed, and an increase in the melt viscosity of the resulting film adhesive is also effectively suppressed, which is a phenomenon specific to the nitride ceramic filler, contrary to a general phenomenon known so far (the specific surface area is increased due to the reduction in particle diameter, and the interaction between the fillers is increased). The present invention is based on these findings, and after further investigation, has been completed.

That is, the above-described problems of the present invention can be solved by the following means.

[1]

A thermally conductive adhesive composition including an epoxy resin (A), an epoxy resin curing agent (B), a polymer component (C), and a nitride ceramic filler (D),
wherein the nitride ceramic filler (D) satisfies the following conditions (1) to (3), and
wherein a proportion of the nitride ceramic filler (D) in a total content of the epoxy resin (A), the epoxy resin curing agent (B), the polymer component (C), and the nitride ceramic filler (D) is 25 to 65% by volume:
(1) an image analysis average particle diameter is 0.1 to 2.5 μm;
(2) an image analysis circularity is 0.7 or more; and
(3) an image analysis maximum particle diameter is 10.0 μm or less.
   [2]

The thermally conductive adhesive composition described in [1], wherein when a film adhesive formed using the adhesive composition is heated at a rate of 5° C./min from 25° C., a melt viscosity at 70° C. is 15000 to 50000 Pa·s.

[3]

The thermally conductive adhesive composition described in [1] or [2], wherein when a film adhesive formed using the adhesive composition is heated at a rate of 5° C./min from 25° C., a melt viscosity at 120° C. is 500 to 10000 Pa·s.

[4]

The thermally conductive adhesive composition described in any one of [1] to [3], wherein a film adhesive formed using the adhesive composition gives a cured product having a thermal conductivity of 1.0 W/m·K or more after thermal curing.

[5]

The thermally conductive adhesive composition described in any one of [1] to [4], wherein the nitride ceramic filler (D) is a pulverized and deaggregated product.

[6]

A method of producing the thermally conductive adhesive composition described in any one of [1] to [5], the method including subjecting a nitride ceramic filler to a pulverization and deaggregation treatment to prepare the nitride ceramic filler as the nitride ceramic filler (D) satisfying the above conditions (1) to (3), and obtaining the thermally conductive adhesive composition using the nitride ceramic filler (D).

[7]

A thermally conductive film adhesive obtained from the thermally conductive film adhesive composition described in any one of [1] to [5].

[8]

The thermally conductive film adhesive described in [7], having a thickness of 1 to 10 μm.

[9]

A dicing die attach film obtained by laminating a dicing film and the thermally conductive film adhesive described in [7] or [8].

[10]

A semiconductor package wherein a semiconductor chip and a circuit board, or semiconductor chips are bonded with a thermally cured product of the thermally conductive film adhesive described in [7] or [8].

[11]

A method of producing a semiconductor package, including:
a first step of providing an adhesive layer by thermocompression bonding the thermally conductive film adhesive described in [7] or [8] to a back surface of a semiconductor wafer in which at least one semiconductor circuit is formed on a surface, and providing a dicing film via the adhesive layer;
a second step of integrally dicing the semiconductor wafer and the adhesive layer to obtain a semiconductor chip with an adhesive layer, which includes the semiconductor chip and a piece of the adhesive, on the dicing film;
a third step of separating the semiconductor chip with an adhesive layer from the dicing film and thermocompression bonding the semiconductor chip with an adhesive layer and a circuit board via the adhesive piece; and
a fourth step of thermally curing the adhesive layer.
   [12]

The method of producing a semiconductor package described in [11], wherein the first step is a step of thermocompression-bonding the dicing die attach film described in [9] to a back surface of the semiconductor wafer.

The numerical ranges indicated with the use of the term “to” in the present invention refer to ranges including the numerical values before and after the term “to” respectively as the lower limit and the upper limit.

In the present invention, (meth)acryl means either or both of acryl and methacryl. The same applies to (meth)acrylate.

### Advantageous Effects of Invention

The thermally conductive adhesive composition of the present invention can suppress aggregation of fillers in the resulting film adhesive and can also suppress an increase in the melt viscosity of the film adhesive while the nitride ceramic filler has a smaller particle diameter. The method of producing a thermally conductive adhesive composition according to the present invention is suitable as a method of preparing the thermally conductive adhesive composition of the present invention.

In addition, in the thermally conductive film adhesive of the present invention, aggregation of fillers can be suppressed, and an increase in the melt viscosity of the adhesive can also be suppressed while the thermally conductive film adhesive contains a nitride ceramic filler having a smaller particle diameter.

Further, in the semiconductor package of the present invention, the semiconductor chip is bonded via the thermally conductive film adhesive having the above excellent characteristics, voids on the bonding surface are suppressed, and the heat dissipation is excellent. The method of producing a semiconductor package according to the present invention is suitable as a method of producing the semiconductor package of the present invention.

### BRIEF DESCRIPTION OF DRAWINGS

FIG. 1 is a schematic longitudinal cross-sectional view illustrating a preferred embodiment of a first step of a method of producing a semiconductor package of the present invention.

FIG. 2 is a schematic longitudinal cross-sectional view illustrating a preferred embodiment of a second step of a method of producing a semiconductor package of the present invention.

FIG. 3 is a schematic longitudinal cross-sectional view illustrating a preferred embodiment of a third step of a method of producing a semiconductor package of the present invention.

FIG. 4 is a schematic longitudinal cross-sectional view illustrating a preferred embodiment of a step of connecting a bonding wire of a method of producing a semiconductor package of the present invention.

FIG. 5 is a schematic longitudinal cross-sectional view illustrating an example of an embodiment of multistacking of a method of producing a semiconductor package of the present invention.

FIG. 6 is a schematic longitudinal cross-sectional view illustrating an example of an embodiment of another multistacking of a method of producing a semiconductor package of the present invention.

FIG. 7 is a schematic longitudinal cross-sectional view illustrating a preferred embodiment of a semiconductor package produced by a method of producing a semiconductor package of the present invention.

### DESCRIPTION OF EMBODIMENTS

### <<Adhesive Composition>>

The thermally conductive adhesive composition of the present invention (hereinafter, also referred to as an adhesive composition of the present invention) is a composition suitable for forming a thermally conductive film adhesive of the present invention (hereinafter, referred to as a film adhesive of the present invention).

The adhesive composition of the present invention includes an epoxy resin (A), an epoxy resin curing agent (B), a polymer component (C), and a nitride ceramic filler (D),
wherein the nitride ceramic filler (D) satisfies the following conditions (1) to (3), and
wherein a proportion of the nitride ceramic filler (D) in a total content of the epoxy resin (A), the epoxy resin curing agent (B), the polymer component (C), and the nitride ceramic filler (D) is 25 to 65% by volume:
(1) an image analysis average particle diameter is 0.1 to 2.5 μm;
(2) an image analysis circularity is 0.7 or more; and
(3) an image analysis maximum particle diameter is 10.0 μm or less.

Hereinafter, in the present specification, the epoxy resin (A) may be referred to as component (A), the epoxy resin curing agent (B) may be referred to as component (B), the polymer component (C) may be referred to as component (C), and the nitride ceramic filler (D) may be referred to as component (D).

In the present invention, the image analysis average particle diameter means an average value of the projected area circle equivalent diameters of the particles in the observation field as obtained by image analysis. The image analysis maximum particle diameter means the maximum value of the projected area circle equivalent diameters of the particles in the observation field as obtained by image analysis.

The image analysis is performed by placing 1.0 g of a nitride ceramic filler (dry product) on a glass plate while using an image analysis particle size distribution analyzer (Portable PITA, manufactured by Seishin Enterprise Co., Ltd.).

Conditions for image analysis are as follows.
Camera: magnification 250×, autofocus (AF) camera
Observation field (measurement region): 679.428 μm×905.904 μm
Number of visual fields observed: 1
Image processing software: OpenCV (Open Source Computer Vision Library)
Measured particle diameter: 0.1 to 10000 μm
Degree of unevenness: 0.9 or more
Binarization: Automatic

When the observation is performed under the above conditions, about 1500 particles of the nitride ceramic filler are observed in the observation field. Particles that fall on the outline of the observation field (particles whose entire particle cannot be observed) are excluded from the data. Particles that are clearly overlapped in the observation field and cannot be observed as a whole are also excluded from the data. Finally, the number of particles that are data acquisition targets is about 1300. In the image analysis, data is usually acquired for 1000 or more particles.

The image analysis circularity means an average value of circularity of each particle in the observation field as obtained by the aforementioned image analysis. The circularity of each particle is a value calculated by the following formula based on the projected area and the perimeter of each particle. The perimeter is measured using image processing software OpenCV.

Circularity=4π×Projected area of particle(μm²)/(Perimeter of particle(μm))²

In the adhesive composition of the present invention, the shape of the nitride ceramic filler is controlled so that the image analysis average particle diameter is 0.1 to 2.5 μm, the image analysis circularity is 0.7 or more, and the image analysis maximum particle diameter is 10.0 μm or less as defined in (1) to (3) above. The shape satisfying the above (1) to (3) is different from the shape of a commercially available nitride ceramic filler, and is realized, for example, by subjecting a commercially available nitride ceramic filler to a pulverization and deaggregation treatment. Further, the proportion of the nitride ceramic filler (D) in the total content of the epoxy resin (A), the epoxy resin curing agent (B), the polymer component (C), and the nitride ceramic filler (D) in the adhesive composition of the present invention is controlled to be from 25 to 65% by volume. As a result, at the time of forming the film adhesive, aggregation of the nitride ceramic filler due to mixing with the resin component containing the epoxy resin (A) and the polymer component (C) can be suppressed, the melt viscosity of the resulting film adhesive can also be suppressed, and a high-performance thermally conductive film adhesive can thus be obtained. The reason for this may be attributed to the hardness of the nitride ceramic filler. It is considered that one of the reasons is that when the nitride ceramic filler is subjected to a pulverization and deaggregation treatment to cause the fillers to collide with each other, the corners are rounded, the circularity is improved, and even when the particle diameter is reduced, the specific surface area does not increase but rather tends to decrease. As described above, the film adhesive obtained from the adhesive composition of the present invention can suppress the generation of aggregates and the increase in melt viscosity even though the nitride ceramic filler has a smaller particle diameter, and as a result, the generation of voids in the die attach step can be sufficiently suppressed even when used as a thin film adhesive.

In consideration of the reactivity between the epoxy resin (A) and the epoxy resin curing agent (B), the adhesive composition of the present invention is preferably refrigerated for storage at 10° C. or less. The film adhesive of the present invention described later can also be stored under the same condition.

Further, by forming a film adhesive using the adhesive composition of the present invention, it is also possible to reduce the amount of wear of the processing blade when used as a die attach film in a dicing step. In the manufacturing process of the semiconductor package, in a so-called dicing step in which the die-attach film and the semiconductor wafer on which the semiconductor element is formed are integrally cut, the wear rate of the processing blade by the die attach film is preferably small. In the adhesive composition of the present invention, since the particle diameter of the nitride ceramic filler is smaller and the circularity is higher, wear of the processing blade can be suppressed.

The method of controlling the image analysis average particle diameter, the image analysis circularity, and the image analysis maximum particle diameter of the nitride ceramic filler so as to satisfy the conditions (1) to (3) is not particularly limited. For example, such control can be achieved by subjecting the nitride ceramic filler to a pulverization and deaggregation treatment described later.

The image analysis average particle diameter of the nitride ceramic filler is preferably 0.5 to 2.5 μm, more preferably 0.8 to 2.5 μm, still more preferably 1.0 to 2.0 μm, still more preferably 1.1 to 2.0 μm, still more preferably 1.2 to 1.8 μm, and particularly preferably 1.2 to 1.6 μm. When the nitride ceramic filler is boron nitride, the image analysis average particle diameter can be 0.5 to 1.8 μm.

The image analysis circularity of the nitride ceramic filler is preferably 0.75 to 1.0, more preferably 0.80 to 0.99, still more preferably 0.82 to 0.99, and particularly preferably 0.85 to 0.99.

The image analysis maximum particle diameter of the nitride ceramic filler is preferably 9.0 μm or less, more preferably 8.8 μm or less, and still more preferably 8.0 μm or less. Particularly preferred is 7.0 μm or less. The lower limit is not particularly limited, but practically 3.0 μm or more.

The proportion of the nitride ceramic filler (D) in the total content of the epoxy resin (A), the epoxy resin curing agent (B), the polymer component (C), and the nitride ceramic filler (D) is from 25 to 65% by volume. The content of the nitride ceramic filler (D) may be set to be within the above range to impart desired thermal conductivity and melt viscosity to the film adhesive.

The proportion of the nitride ceramic filler (D) in the total content of the components (A) to (D) is preferably 25 to 60% by volume, more preferably 30 to 55% by volume, still more preferably 35 to 55% by volume, and still more preferably 30 to 50% by volume.

The content (vol %) of the nitride ceramic filler (D) can be calculated from the content mass and the specific gravity of each of the components (A) to (D). In the present invention, for the calculation of the vol %, the specific gravities of the components (A) to (C) are all set to 1.2, and the specific gravity of the component (D) is set to the true specific gravity for calculation.

Hereinafter, each component contained in the adhesive composition will be described more specifically.

### <Epoxy Resin (A)>

The epoxy resin (A) can be used without any particular limitation as long as it is a thermosetting resin having an epoxy group, and may be any of liquid, solid, and semi-solid. The liquid in the present invention means that the softening point is less than 25° C. The solid means that the softening point is 60° C. or more. The semi-solid means that the softening point is between the softening point of the liquid and the softening point of the solid (25° C. or more and less than 60° C.). As the epoxy resin (A) used in the present invention, the softening point is preferably 100° C. or less from the viewpoint of being capable of obtaining a film adhesive that can reach low melt viscosity in a preferable temperature range (for example, 60 to 120° C.). Incidentally, in the present invention, the softening point is a value measured by the softening point test (ring and ball) method (measurement condition: in accordance with JIS-2817).

In the epoxy resin (A) used in the present invention, the epoxy equivalent is preferably 500 g/eq or less, and more preferably 150 to 450 g/eq from the viewpoint of increasing the crosslinking density of a cured product, and as a result, increasing the contact ratio between blended nitride ceramic fillers (D) and the contact area between nitride ceramic fillers (D), thus providing higher thermal conductivity. Note that, in the present invention, the epoxy equivalent refers to the number of grams of a resin containing 1 gram equivalent of epoxy group (g/eq).

The weight average molecular weight of the epoxy resin (A) is usually preferably less than 10000 and more preferably 5000 or less. The lower limit is not particularly limited but is practically 300 or more.

The weight average molecular weight is a value obtained by GPC (Gel Permeation Chromatography) analysis (hereinafter, the same applies to other resins unless otherwise specified).

Examples of the skeleton of the epoxy resin (A) include a phenol novolac type, an orthocresol novolac type, a cresol novolac type, a dicyclopentadiene type, a biphenyl type, a fluorene bisphenol type, a triazine type, a naphthol type, a naphthalene diol type, a triphenylmethane type, a tetraphenyl type, a bisphenol A type, a bisphenol F type, a bisphenol AD type, a bisphenol S type, and a trimethylolmethane type. Among these skeletons, a triphenylmethane type, a bisphenol A type, a cresol novolac type, or an orthocresol novolac type is preferable from the viewpoint of being capable of obtaining a film adhesive having low resin crystallinity and good appearance.

The content of the epoxy resin (A) is preferably 3 to 40 parts by mass, preferably 5 to 40 parts by mass, and more preferably 8 to 35 parts by mass, still more preferably 10 to 30 parts by mass, and particularly preferably 20 to 30 parts by mass, based on 100 parts by mass of the total content of components constituting the film adhesive (specifically, components other than a solvent, i.e., a solid content) in the adhesive composition of the present invention. The thermal conductivity of the film adhesive can be improved by adjusting the content to the preferable lower limit or more. On the other hand, by adjusting the content to the preferable upper limit or less, generation of oligomer components can be suppressed, and the state of the film (for example, film tack property) can be prevented from changing with small change in temperature.

### <Epoxy Resin Curing Agent (B)>

As the epoxy resin curing agent (B), optional curing agents such as amines, acid anhydrides, and polyhydric phenols can be used. In the present invention, a latent curing agent is preferably used from the viewpoint of allowing the epoxy resin (A) and the polymer component (C) to have a low melt viscosity, and being capable of providing a thermally conductive adhesive composition that exhibits curability at a high temperature more than a certain temperature, has rapid curability, and further has high storage stability that enables long-term storage at room temperature.

Examples of the latent curing agent include a dicyandiamide compound, an imidazole compound, a curing catalyst composite-based polyhydric phenol compound, a hydrazide compound, a boron trifluoride-amine complex, an amine imide compound, a polyamine salt, a modified product thereof, or those of a microcapsule type. In the present invention, it is more preferable to use an imidazole compound from the viewpoint of adjusting the melt viscosity at 70° C. and the melt viscosity at 120° C. of the thermally conductive film adhesive to satisfy the above preferable ranges.

These may be used singly, or in combination of two or more types thereof.

The content of the epoxy resin curing agent (B) per 100 parts by mass of the epoxy resin (A) is preferably 0.5 to 100 parts by mass, and more preferably 1 to 80 parts by mass. By setting the content to the above preferable lower limit or more, a curing time can be reduced. On the other hand, by setting the content to the preferable upper limit or less, failures in a reliability test conducted after the film adhesive is incorporated into a semiconductor, the failures being caused by excessive curing agent remaining in the film adhesive absorbing moisture, can be reduced.

### <Polymer Component (C)>

The polymer component (C) has only to be a component that suppresses a film tack property at normal temperature (25° C.) (property that the film state is likely to change by even a little temperature change) and imparts sufficient adhesiveness and film formability (film forming property) when the film adhesive is formed. Examples thereof include a natural rubber, a butyl rubber, an isoprene rubber, a chloroprene rubber, an ethylene-vinyl acetate copolymer, an ethylene-(meth)acrylic acid copolymer, an ethylene-(meth)acrylic acid ester copolymer, a polybutadiene resin, a polycarbonate resin, a thermoplastic polyimide resin, polyamide resins such as 6-nylon and 6,6-nylon, a phenoxy resin, a (meth)acrylic resin, polyester resins such as polyethylene terephthalate and polybutylene terephthalate, a polyamideimide resin, a fluororesin, and a polyurethane resin. These polymer components (C) may be used singly, or in combination of two or more types thereof. As the polymer component (C), at least one kind of a phenoxy resin, a (meth)acrylic resin, or a polyurethane resin is preferable.

The polymer component (C) should have a weight average molecular weight of 10000 or more. The upper limit is not particularly limited but is practically 5000000 or less.

The weight average molecular weight of the polymer component (C) is a value determined by GPC (Gel Permeation Chromatography) in terms of polystyrene. Hereinafter, the value of the weight average molecular weight of the specific polymer component (C) has the same meaning.

The glass transition temperature (Tg) of the polymer component (C) is preferably less than 100° C., and more preferably less than 90° C. The lower limit is preferably 0° C. or more, and more preferably 10° C. or more.

The glass transition temperature of the polymer component (C) is a glass transition temperature measured by DSC at a temperature elevation rate of 0.1° C./min. Hereinafter, the value of the glass transition temperature of the specific polymer component (C) has the same meaning.

Note that in the present invention, with regard to the epoxy resin (A) and a resin which can have an epoxy group such as a phenoxy resin among the polymer components (C), a resin having an epoxy equivalent of 500 g/eq or less is classified into the epoxy resin (A), and a resin which does not correspond to the above resin is classified into the polymer component (C).

### (Phenoxy Resin)

The phenoxy resin has a structure similar to that of the epoxy resin (A) and is thus preferable as the polymer component (C) from the viewpoint of good compatibility. Inclusion of the phenoxy resin can exert an excellent effect on adhesion performance.

The phenoxy resin can be obtained by a usual method. For example, the phenoxy resin can be obtained by a reaction of a bisphenol or biphenol compound with epihalohydrin such as epichlorohydrin, or a reaction of liquid epoxy resin with a bisphenol or biphenol compound.

The weight-average molecular weight of the phenoxy resin is preferably 10000 or larger and more preferably from 10000 to 100000.

Further, the amount of epoxy group remaining in a small amount in the phenoxy resin is an epoxy equivalent of preferably 5000 g/eq or more.

The glass transition temperature (Tg) of the phenoxy resin is preferably less than 100° C., and more preferably less than 90° C. The lower limit is preferably 0° C. or more, and more preferably 10° C. or more.

### ((Meth)Acrylic Resin)

The (meth)acrylic resin is not particularly limited, and a resin composed of a known (meth)acrylic copolymer can be widely used as a film component of the film adhesive.

Examples of the (meth)acrylic resin include poly(meth)acrylic acid esters and derivatives thereof. Examples thereof include copolymers containing, as a monomer component, 2-hydroxyethyl acrylate, 2-hydroxyethyl methacrylate, 2-hydroxypropyl acrylate, 2-hydroxypropyl methacrylate, acrylic acid, methacrylic acid, itaconic acid, glycidylmethacrylate, glycidylacrylate, and the like.

In addition, preferred is a copolymer using, as a monomer, a (meth)acrylic acid ester having a cyclic skeleton (e.g., a (meth)acrylic acid cycloalkyl ester, a (meth)acrylic acid benzyl ester, isobornyl (meth)acrylate, dicyclopentanyl (meth)acrylate, dicyclopentenyl (meth)acrylate, dicyclopentenyloxyethyl (meth)acrylate, imide(meth)acrylate).

Also preferred is a monomer component such as a (meth)acrylic acid alkyl ester having a C₁₋₁₈ alkyl (e.g., methyl (meth)acrylate, ethyl (meth)acrylate, propyl (meth)acrylate, butyl (meth)acrylate).

Also, these monomer components may be copolymerized with vinyl acetate, (meth)acrylonitrile, styrene, or the like.

Further, a (meth)acrylic resin having a hydroxy group is preferable because compatibility with the epoxy resin is favorable.

The weight-average molecular weight of the (meth)acrylic copolymer is preferably 10000 to 2000000, and more preferably 100000 to 1500000. By adjusting the weight-average molecular weight to a level within the preferable range, a tack property can be reduced and increase in the melt viscosity can also be suppressed.

The glass transition temperature of the (meth)acrylic copolymer is in a range of preferably −35° C. to 50° C., more preferably −10° C. to 50° C., still more preferably 0° C. to 40° C., and particularly preferably 0° C. to 30° C. By adjusting the glass transition temperature to a level within the preferable range, a tack property can be reduced and generation of voids between the semiconductor wafer and the film adhesive, and the like can be suppressed.

### (Polyurethane Resin)

The polyurethane resin is a polymer having a urethane (carbamic acid ester) bond in the main chain. The polyurethane resin has a constituent unit derived from a polyol and a constituent unit derived from a polyisocyanate, and may further have a constituent unit derived from a polycarboxylic acid. One kind of the polyurethane resin may be used singly, or two or more kinds thereof may be used in combination.

The Tg of the polyurethane resin is usually 100° C. or lower, preferably 60° C. or lower, more preferably 50° C. or lower, and also preferably 45° C. or lower.

The weight-average molecular weight of the polyurethane resin is not particularly limited, and a polyurethane resin having a weight-average molecular weight within a range of 5000 to 500000 is usually used.

The polyurethane resin can be synthesized by an ordinarily method, and can also be obtained from the market. Examples of a commercially available product that can be applied as the polyurethane resin include Dynaleo VA-9320M, Dynaleo VA-9310MF, or Dynaleo VA-9303MF (all manufactured by TOYOCHEM CO., LTD.).

The content of the polymer component (C) per 100 parts by mass of the epoxy resin (A) is preferably 1 to 40 parts by mass, more preferably 5 to 35 parts by mass, and even more preferably 10 to 30 parts by mass. The rigidity and flexibility of the thermally conductive film adhesive before curing can be controlled by adjusting the content to such a range. The state of the film becomes favorable (film tack property is reduced), and thus film brittleness can also be suppressed.

### <Nitride Ceramic Filler (D)>

The nitride ceramic filler (D) is nitride ceramic powder, and is not particularly limited as long as it is a nitride ceramic filler satisfying the above conditions (1) to (3). The nitride ceramic filler (D) contributes to imparting thermal conductivity to the adhesive composition and the film adhesive.

Examples of the nitride ceramic include nitride ceramics such as aluminum nitride, boron nitride, and silicon nitride. From the viewpoint of enhancing thermal conductivity, aluminum nitride is preferable.

The nitride ceramic filler (D) is preferably a pulverized and deaggregated product obtained by subjecting the nitride ceramic filler to a pulverization and deaggregation treatment described later.

The thermal conductivity of the nitride ceramic filler (D) is not particularly limited, and is preferably 12 W/m·K or more, more preferably 30 W/m·K or more, still more preferably 50 W/m·K or more, and still more preferably 100 W/m·K or more.

When the thermal conductivity of the nitride ceramic filler (D) is equal to or more than the preferable lower limit, the amount of the nitride ceramic filler (D) blended in order to obtain a desired thermal conductivity can be reduced. This more effectively suppresses an increase in the melt viscosity of the adhesive film, and more effectively improves a property of embedding the film into unevenness of a substrate at the time of compression bonding to the substrate, thus enabling more effectively suppressing generation of voids.

In the present invention, the thermal conductivity of the nitride ceramic filler (D) means a thermal conductivity at 25° C., and literature values for each material can be used. In a case where the value is not described in the literature, a value measured according to JIS R 1611 can be used instead.

Note that when the nitride ceramic filler (D) has thermal conductivity anisotropy and exhibits different thermal conductivities in a plurality of directions, the highest thermal conductivity is defined as the thermal conductivity of the nitride ceramic filler.

The nitride ceramic filler (D) may be subjected to surface treatment or surface modification. Examples of an agent or compound used for such surface treatment and surface modification (collectively referred to as a surface treatment agent) include a silane coupling agent, phosphoric acid or a phosphoric acid compound, and a surfactant. In addition to the items described in the present specification, for example, the descriptions of the silane coupling agent, the phosphoric acid or phosphoric acid compound, and the surfactant in the section of the thermally conductive filler in WO 2018/203527 or the section of the aluminum nitride filler in WO 2017/158994 can be applied. When the nitride ceramic filler (D) subjected to surface treatment or surface modification is used in the present invention, the conditions (1) to (3) are satisfied under surface treated or surface modified conditions.

Examples of a method for mixing the nitride ceramic filler (D) with resin components such as the epoxy resin (A), the epoxy resin curing agent (B), and the polymer component (C) include: a method in which a powdery nitride ceramic filler, and if necessary, a silane coupling agent; phosphoric acid or a phosphoric acid compound; a surfactant, and the like are directly mixed with the resin components (integral blending method); or a method in which the above resin components are blended with a slurry of the nitride ceramic filler (D) as obtained by dispersing the nitride ceramic filler (D) treated with a surface treatment agent such as a silane coupling agent, phosphoric acid or a phosphoric acid compound, or a surfactant in an organic solvent.

The method of treating the nitride ceramic filler (D) with a silane coupling agent; phosphoric acid or a phosphoric acid compound; a surfactant, or the like is not particularly limited, and examples thereof include: a wet method in which the nitride ceramic filler (D) is mixed with a silane coupling agent; phosphoric acid or a phosphoric acid compound; a surfactant, or the like in a solvent; a dry method in which the nitride ceramic filler (D) is treated with a silane coupling agent; phosphoric acid or a phosphoric acid compound; a surfactant, or the like in a gas phase; and the integral blending method described above.

In particular, the aluminum nitride particles contribute to high thermal conductivity, but tend to generate ammonium ions due to hydrolysis. It is therefore preferable that the aluminum nitride particles are used in combination with a phenol resin having a low moisture absorption rate or hydrolysis is suppressed by surface modification. As a method for surface modification of the aluminum nitride particles, a method of providing a surface layer with an oxide layer of aluminum oxide to improve water resistance and then preforming surface treatment with phosphoric acid or a phosphoric acid compound to improve affinity with the resin is particularly preferable. In addition, it is also preferable to additionally use an ion trapping agent in combination.

The silane coupling agent is a compound in which at least one hydrolyzable group such as an alkoxy group or an aryloxy group is bonded to a silicon atom. In addition to these groups, an alkyl group, an alkenyl group, or an aryl group may be bonded to the silicon atom. The alkyl group is preferably an alkyl group substituted with an amino group, an alkoxy group, an epoxy group, or a (meth)acryloyloxy group, and more preferably an alkyl group substituted with an amino group (preferably, a phenylamino group), an alkoxy group (preferably, a glycidyloxy group), or a (meth)acryloyloxy group.

Examples of the silane coupling agent include 2-(3,4-epoxycyclohexyl)ethyltrimethoxysilane, 3-glycidyloxypropyltrimethoxysilane, 3-glycidyloxypropyltriethoxysilane, 3-glycidyloxypropylmethyldimethoxysilane, 3-glycidyloxypropylmethyldiethoxysilane, dimethyldimethoxysilane, dimethyldiethoxysilane, methyltrimethoxysilane, methyltriethoxysilane, phenyltrimethoxysilane, phenyltriethoxysilane, N-phenyl-3-aminopropyltrimethoxysilane, 3-methacryloyloxypropylmethyldimethoxysilane, 3-methacryloyloxypropyltrimethoxysilane, 3-methacryloyloxypropylmethyldiethoxysilane, and 3-methacryloyloxypropyltriethoxysilane.

The surface treatment agent such as a silane coupling agent, phosphoric acid or a phosphoric acid compound, or a surfactant is preferably contained in an amount of 0.1 to 2.0 parts by mass based on 100 parts by mass of the nitride ceramic filler (D). By setting such an amount ratio, it is possible to suppress the occurrence of peeling at an adhesion interface due to volatilization of an excessive silane coupling agent, a surfactant, and the like in a semiconductor assembly heating step (e.g., a reflow step) while suppressing aggregation of the nitride ceramic filler (D), and to improve adhesiveness.

In the adhesive composition of the present invention, in addition to the nitride ceramic filler (D), an inorganic filler other than the nitride ceramic filler can also be used. Examples of the inorganic filler include inorganic fillers usually used in the adhesive composition.

The content of the nitride ceramic filler is preferably 70 mass % or more, more preferably 80 mass % or more, and still more preferably 90 mass % or more based on the total amount of the filler. In the adhesive composition of the present invention, the whole amount of the filler may be the nitride ceramic filler (D).

### <Other Additives>

In addition to the epoxy resin (A), the epoxy resin curing agent (B), the polymer component (C), and the nitride ceramic filler (D), the adhesive composition of the present invention may further contain additives such as an organic solvent (MEK or the like), an ion trapping agent (ion capturing agent), a curing catalyst, a viscosity adjusting agent, an antioxidant, a flame retardant, a coloring agent, and/or a stress relaxing agent such as butadiene-series rubber and silicone rubber, as long as the effect of the present invention is not impaired. For example, description of another additive in WO-A-2017/158994 can be applied.

The proportion of the total content of the epoxy resin (A), the epoxy resin curing agent (B), the polymer component (C), and the nitride ceramic filler (D) in the adhesive composition of the present invention is not particularly limited as long as the film adhesive of the present invention can be obtained. The proportion can be, for example, 60 to 95% by mass, and is preferably 70 to 90% by mass.

The adhesive composition of the present invention can be suitably used for obtaining the film adhesive of the present invention. However, the adhesive composition of the present invention is not limited to the film adhesive, and can also be suitably used for a liquid adhesive, for example.

The adhesive composition of the present invention can be obtained by mixing the above components at a temperature at which the epoxy resin (A) is practically not cured. The order of mixing is not particularly limited. For example, resin components such as the epoxy resin (A) and the polymer component (C) may be mixed together with a solvent as necessary, and the nitride ceramic filler (D), the epoxy resin curing agent (B), and the silane coupling agent may then be mixed. In this case, the mixing in the presence of the epoxy resin curing agent (B) may be performed at a temperature at which the epoxy resin (A) is practically not cured, and the mixing of the resin components in the absence of the epoxy resin curing agent (B) may be performed at a higher temperature.

From the viewpoint of ensuring that the nitride ceramic filler (D) satisfies the conditions (1) to (3), the method of producing the adhesive composition of the present invention preferably includes a step of pulverizing and deaggregating the nitride ceramic filler. The pulverization and deaggregation treatment step may be a step including subjecting the nitride ceramic filler to either or both of a pulverization treatment and a deaggregation treatment. The conditions for the pulverization and deaggregation treatment can be appropriately set so that the obtained nitride ceramic filler satisfies the above conditions (1) to (3).

The pulverization and deaggregation treatment can be performed using a pulverization/deaggregation machine such as a jet mill, a bead mill, a hammer mill, or a roller mill.

Conditions for the pulverization and deaggregation treatment are appropriately set according to the nitride ceramic filler to be used and the processing machine. For example, in the case of treatment with a jet mill, when the treatment amount is 7 to 9 kg/hr and the nozzle pressure is 0.6 to 0.8 MPa, the conditions (1) to (3) can be achieved with high efficiency. In the case of treatment with a bead mill, when the bead material is zirconia-based, the bead particle diameter is 1.5 mm, the bead filling rate is 70%, the feed amount is 0.8 to 1.0 L/hr, the auxiliary agent is ethanol, and the mill peripheral speed is 4.0 m/s, the conditions (1) to (3) can be achieved with high efficiency.

### <Characteristics of Film Adhesive>

### (Melt Viscosity)

When a film adhesive obtained by using the adhesive composition of the present invention (hereinafter, also referred to as a film adhesive of the present invention) is heated at a rate of 5° C./min from 25° C., the melt viscosity at 70° C. preferably is in a range of 15000 to 50000 Pa·s. This melt viscosity at 70° C. is more preferably in a range of 15000 to 45000 Pa·s, still more preferably in a range of 15000 to 40000 Pa·s, and particularly preferably in a range of 16000 to 36000 Pa·s. By adjusting the melt viscosity at 70° C. to a level within the preferable range, generation of voids between the semiconductor wafer and the film adhesive can be further reduced when the film adhesive is bonded to the semiconductor wafer.

Also, when the film adhesive of the present invention is heated at a rate of 5° C./min from 25° C., the melt viscosity at 120° C. is preferably in a range of 500 to 10000 Pa·s. The melt viscosity at 120° C. is more preferably in a range of 800 to 9000 Pa·s, still more preferably in a range of 1000 to 8000 Pa·s, still more preferably in a range of 1500 to 6000 Pa·s, still more preferably in a range of 1500 to 4000 Pa·s, and particularly preferably in a range of 1500 to 3000 Pa·s. By adjusting the melt viscosity at 120° C. to a level within the preferable range, generation of voids between uneven portions on the circuit board can be further reduced when the semiconductor chip provided with the film adhesive is thermocompression bonded onto the circuit board.

In the present invention, the melt viscosity is determined by measuring a change in viscosity resistance in a temperature range of 25 to 200° C. at a temperature elevation rate of 5° C./min from 25° C. for a thermally conductive film adhesive before thermal curing while using a rheometer (trade name: RS6000, manufactured by Haake) and then calculating the melt viscosities at 70° C. and 120° C. from the obtained temperature-viscosity resistance curve. Specifically, the measurement method described in Examples can be used as a reference.

Here, the thermally conductive film adhesive before thermal curing in the measurement of the melt viscosity means a thermally conductive film adhesive that is not exposed to a temperature condition of 25° C. or more for 1 month or more.

The melt viscosity can be adjusted to the above range by the content of the nitride ceramic filler (D), further, the type of the nitride ceramic filler (D), as well as the type or content of the coexisting compounds or resins such as the epoxy resin (A), the epoxy resin curing agent (B), the polymer component (C), and the like.

### (Thermal Conductivity)

In the film adhesive of the present invention, the thermal conductivity after thermal curing is preferably 1.0 W/m·K or more. The thermal conductivity is more preferably 1.5 W/m·K or more. When the thermal conductivity is less than the preferable lower limit, there is a tendency that generated heat is less likely to be released to outside of the package. The film adhesive of the present invention exhibits such excellent thermal conductivity after thermal curing. Thus, a semiconductor package having improved efficiency of heat dissipation to the outside of the semiconductor package can be obtained by firmly bonding the film adhesive of the present invention to an adherend such as a semiconductor wafer and a circuit board, followed by thermal curing.

The upper limit of the thermal conductivity is not particularly limited, but is practically, 7.0 W/m·K or less, more preferably 6.5 W/m·K or less, and also preferably 5.0 W/m·K or less. Thus, the film adhesive of the present invention has a thermal conductivity of preferably 1.0 W/m·K to 7.0 W/m·K, more preferably 1.5 to 6.5 W/m·K, and still more preferably 1.5 to 5.0 W/m·K.

Here, the expression “after thermal curing” in the measurement of thermal conductivity means a state in which curing of thermosetting resin has been completed. Specifically, it is a state in which no heat reaction peak is observed when DSC (Differential Scanning calorimeter) measurement is performed at a temperature elevation rate of 10° C./min.

In the present invention, such a thermal conductivity of the film adhesive after thermal curing refers to a value obtained by measuring the thermal conductivity by using a thermal conductivity measurement apparatus (trade name: HC-110, manufacture by Eko Instruments Co., Ltd) according to the heat flow meter method (in accordance with JIS-A1412). Specifically, the measurement method described in Examples can be used as a reference.

The thermal conductivity can be adjusted to the above range by the content of the nitride ceramic filler (D), further, the type of the nitride ceramic filler (D), and the type or content of the coexisting compounds or resins such as the epoxy resin (A), the epoxy resin curing agent (B), the polymer component (C), and the like.

The film adhesive of the present invention also has an insulating property as characteristics thereof.

### <<Film Adhesive and Producing Method Thereof>>

The thermally conductive film adhesive of the present invention is a film adhesive obtained from the adhesive composition of the present invention, and is prepared by including the epoxy resin (A), the epoxy resin curing agent (B), the polymer component (C), and the nitride ceramic filler (D). Among the additives described as other additives in the adhesive composition of the present invention, the additives other than the organic solvent in addition to the above components may be contained.

More specifically, the thermally conductive film adhesive of the present invention is specified as follows:
A thermally conductive film adhesive including an epoxy resin (A), an epoxy resin curing agent (B), a polymer component (C), and a nitride ceramic filler (D),
wherein the nitride ceramic filler (D) satisfies the following conditions (1) to (3), and
wherein a proportion of the nitride ceramic filler (D) in a total content of the epoxy resin (A), the epoxy resin curing agent (B), the polymer component (C), and the nitride ceramic filler (D) is 25 to 65% by volume:
(1) an image analysis average particle diameter is 0.1 to 2.5 μm;
(2) an image analysis circularity is 0.7 or more; and
(3) an image analysis maximum particle diameter is 10.0 μm or less.

When the film adhesive of the present invention is formed using the adhesive composition containing an organic solvent, the solvent is usually removed from the adhesive composition by drying. Thus, the content of the solvent in the film adhesive of the present invention is 1000 ppm (ppm is on a mass basis) or less, and is usually 0.1 to 1000 ppm.

Here, the “film” in the present invention means a thin film having a thickness of 200 μm or less. The shape, size, and the like, other than the thickness, of the film are not particularly limited, and can be appropriately adjusted according to a use form.

The film adhesive of the present invention is in a state before curing, that is, in a state of B-stage.

The film adhesive of the present invention can be suitably used as a die attach film in a semiconductor production process.

The thickness of the film adhesive of the present invention is not particularly limited, but is preferably 1 to 200 μm, and is more preferably 1 to 100 μm, still more preferably 1 to 50 μm, still more preferably 1 to 40 μm, also preferably 1 to 30 μm, also preferably 1 to 20 μm, and also preferably 1 to 10 μm from the viewpoint that the film adhesive can be more sufficiently embedded in unevenness of the surface of the circuit board or the semiconductor chip. The thickness is preferably 2 μm or more, and also preferably 3 μm or more (i.e., in each preferable range of the thickness, the lower limit may be 2 μm or may be preferably 3 μm). By controlling the thickness of the film adhesive as described above, for example, when the film adhesive is used as a die attach film, the film adhesive can be more sufficiently embedded in unevenness of a surface of a circuit board or a semiconductor chip, and is also excellent in thermal conductivity. In addition, an organic solvent can be sufficiently removed during production, and a form exhibiting an appropriate film tack property can be obtained.

The thickness of the film adhesive is a value measured by a contact type linear gauge method (desk-top contact type thickness measurement apparatus).

For example, the film adhesive of the present invention can be formed by preparing the adhesive composition (varnish) of the present invention, applying the composition onto a release-treated substrate film, and drying the composition as necessary. The adhesive composition usually contains an organic solvent.

As the release-treated substrate film, any release-treated substrate film that functions as a cover film of the obtained film adhesive can be used, and a publicly known film can be appropriately employed. Examples thereof include release-treated polypropylene (PP), release-treated polyethylene (PE), or release-treated polyethylene terephthalate (PET).

A publicly known method can be appropriately employed as an application method, and examples thereof include methods using a roll knife coater, a gravure coater, a die coater, a reverse coater, and the like.

The drying may be performed by removing the organic solvent from the adhesive composition without curing the epoxy resin (A) thereby forming a film adhesive. The drying can be performed, for example, by holding the composition at a temperature of 80 to 150° C. for 1 to 20 minutes.

The film adhesive of the present invention may be formed of the film adhesive of the present invention alone, or may have a form obtained by bonding a release-treated substrate film described above to at least one surface of the film adhesive. Further, a dicing die attach film may be formed integrally with the dicing film. The film adhesive of the present invention may be a form obtained by cutting the film into an appropriate size, or a form obtained by winding the film into a roll form.

### <<Semiconductor Package and Producing Method Thereof>>

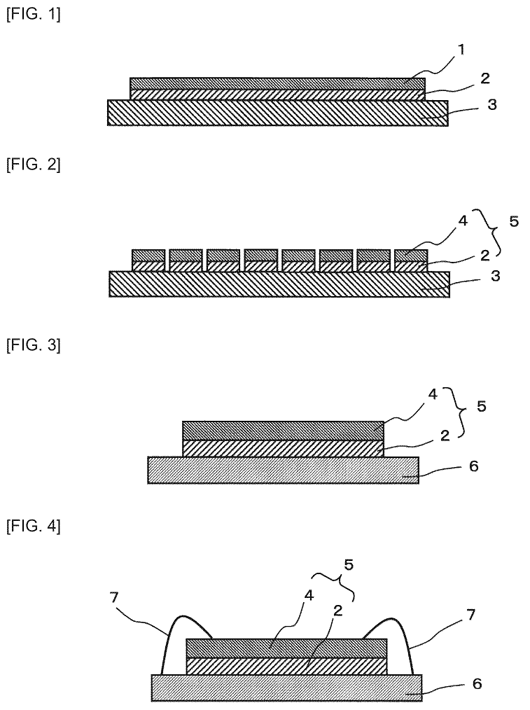

Then, preferred embodiments of a semiconductor package and a method of producing the same of the present invention will be described in detail with reference to the drawings. Note that, in the descriptions and drawings below, the same reference numerals are given to the same or corresponding components, and overlapping descriptions will be omitted. FIGS. 1 to 7 are schematic longitudinal cross-sectional views each illustrating a preferred embodiment of each step of a method of producing a semiconductor package of the present invention.

In the method of producing a semiconductor package of the present invention, as a first step, as illustrated in FIG. 1, the film adhesive (die attach film) of the present invention is thermocompression bonded to the back surface of a semiconductor wafer 1 in which at least one semiconductor circuit is formed on a surface (that is, the back surface is a surface of the semiconductor wafer 1 on which the semiconductor circuit is not formed) to provide an adhesive layer 2 (film adhesive 2) (lamination step), and then a dicing film 3 is provided via this adhesive layer 2 (film adhesive 2). In FIG. 1, the film adhesive 2 is illustrated smaller than the dicing film 3, but the sizes (areas) of both films are set, if appropriate, according to the purpose. For the condition of thermocompression bonding, thermocompression bonding is performed at a temperature at which the epoxy resin (A) is not thermally cured actually. For example, the condition of a temperature of 70° C. and a pressure of 0.3 MPa is exemplified.

As the semiconductor wafer 1, a semiconductor wafer in which at least one semiconductor circuit is formed on the surface can be appropriately used. Examples of such a wafer include a silicon wafer, a SiC wafer, and a GaS wafer.

An apparatus used when the film adhesive 2 of the present invention is provided on the back surface of the semiconductor wafer 1 is not particularly limited. For example, a publicly known apparatus such as a roll laminator and a manual laminator can be used, if appropriate.

In the above, the die attach film and the dicing film are separately attached. However, when the film adhesive of the present invention is in the form of a dicing die attach film, the film adhesive and the dicing film can be integrally bonded.

Next, as a second step, as illustrated in FIG. 2, the semiconductor wafer 1 and the adhesive layer 2 are simultaneously diced to give a semiconductor chip with an adhesive layer 5 on the dicing film 3, the semiconductor chip with an adhesive layer 5 including a semiconductor chip 4 obtained by dicing the semiconductor wafer 1 and a piece of film adhesive 2 obtained by dicing the film adhesive 2.

The dicing film 3 is not particularly limited, and a known dicing film can be used, if appropriate. Further, an apparatus used for dicing is not particularly limited, and a publicly known dicing apparatus can be appropriately used.

Next, as the third step, the semiconductor chip with an adhesive layer is separated from the dicing film. At this time, if necessary, the dicing film may be cured with energy rays to reduce the adhesion strength. The peeling can be performed by picking up the semiconductor chip with an adhesive layer 5. Then, as illustrated in FIG. 3, the semiconductor chip with an adhesive layer 5 and the circuit board 6 are thermocompression bonded via a piece of film adhesive 2, to mount the semiconductor chip with an adhesive layer 5 on the circuit board 6 (die attach step).

As the circuit board 6, a substrate where a semiconductor circuit is formed on the surface can be appropriately used. Examples of such a substrate include a print circuit board (PCB), various lead frames, and a substrate where electronic components such as a resistive element and a capacitor are mounted on a surface of the substrate.

A method of mounting the semiconductor chip with an adhesive layer 5 on such a circuit board 6 is not particularly limited. A conventional method that enables bonding the semiconductor chip with an adhesive layer 5 to the circuit board 6 or the electronic component mounted on the surface of the circuit board 6 by utilizing a piece of adhesive 2 can be appropriately employed. Examples of such a mounting method include a publicly known heating and pressurizing method such as a method using a mounting technique using a flip chip bonder having a heating function from the upper part, a method using a die bonder having a heating function from only the lower part, and a method using a laminator.

As such, mounting the semiconductor chip with an adhesive layer 5 on the circuit board 6 via a piece of adhesive 2 formed from the film adhesive of the present invention allows the piece of adhesive 2 to conform to the unevenness on the circuit board 6, which unevenness is formed due to electronic components, and thereby enables firmly adhering and fixing the semiconductor chip 4 and the circuit board 6.

Then, as a fourth step, the piece of adhesive 2 is thermally cured.

The temperature of the thermal curing is not particularly limited as long as the temperature is equal to or higher than a temperature at which thermal curing starts in the film adhesive of the present invention, and is set, if appropriate, depending on the types of the epoxy resin (A), the polymer component (C), and the epoxy curing agent (B) used. For example, the temperature is preferably from 100 to 180° C. and more preferably from 140 to 180° C. from the viewpoint of curing in a shorter time. When the temperature is less than the thermal curing start temperature, thermal curing does not sufficiently proceed, and as a result, the strength of the adhesive layer 2 tends to decrease. On the other hand, when the temperature is more than the above upper limit, the epoxy resin, the curing agent, the additives, and the like in the film adhesive volatilize during the curing process and thus tend to foam.

Also, the time for curing treatment is preferably, for example, 10 to 120 minutes.

In the method of producing a semiconductor package of the present invention, it is preferable that the circuit board 6 and the semiconductor chip with an adhesive layer 5 are connected via a bonding wire 7 as illustrated in FIG. 4. Such a connection method is not particularly limited, and a publicly known method, for example, a wire bonding method or a TAB (Tape Automated Bonding) method can be appropriately employed.

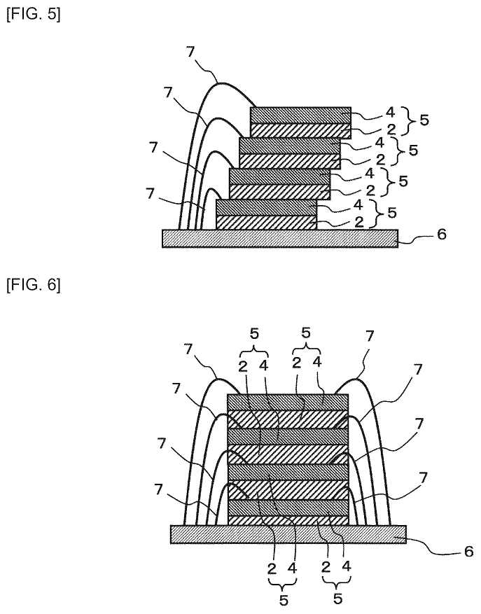

Further, a plurality of semiconductor chips 4 can be stacked by thermocompression bonding another semiconductor chip 4 to a surface of the mounted semiconductor chip 4, performing thermal curing, and then connecting the semiconductor chips 4 again to the circuit board 6 by wire bonding. Examples of the stacking method include a method of stacking the semiconductor chips in slightly different positions as illustrated in FIG. 5, and a method of stacking the semiconductor chips by increasing the thickness of the piece of adhesive 2 of the second layer or later and thereby embedding the bonding wire 7 in each piece of adhesive 2 as illustrated in FIG. 6.

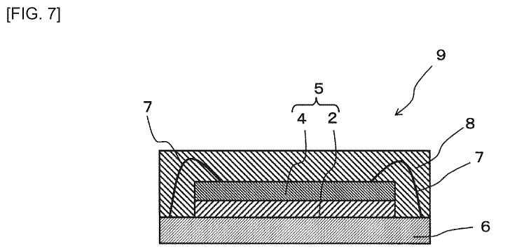

In the method of producing a semiconductor package of the present invention, it is preferable to seal the circuit board 6 and the semiconductor chip with an adhesive layer 5 by using a sealing resin 8 as illustrated in FIG. 7. In this way, the semiconductor package 9 can be obtained. The sealing resin 8 is not particularly limited, and a publicly known sealing resin that can be used for the production of the semiconductor package can be appropriately used. In addition, a sealing method using the sealing resin 8 is not particularly limited, and a publicly known method can be employed, if appropriate.

The semiconductor package of the present invention is produced by the above-described method of producing a semiconductor package. At least one site disposed between a semiconductor chip and a circuit board or between semiconductor chips is bonded with a thermally cured product of the film adhesive of the present invention.

### EXAMPLES

Hereinafter, the present invention will be described in more detail based on Examples and Comparative Examples. However, the present invention is not limited to the following Examples. Also, the room temperature means 25° C., MEK is methyl ethyl ketone, IPA is isopropanol, and PET is polyethylene terephthalate.

### <To Measure Image Analysis Average Particle Diameter, Image Analysis Circularity, and Image Analysis Maximum Particle Diameter of Nitride Ceramic Filler>

The above-described protocols were performed.

### <To Measure Specific Surface Area>

0.8 g of each nitride ceramic filler was thermally dried at 200° C./10 minutes in an oven, and was measured by a BET 1 point method with a mixed gas of He: N₂=3:7 while using a specific surface area meter (Macsorb Model HM-1210).

### <To Measure Melt Viscosity>

Squares having a size of 5.0 cm in length×5.0 cm in width were each cut out from the film adhesive with a release film as obtained in each of Examples and Comparative Examples. The cut samples in which the release film has been peeled off were laminated and bonded on a hot plate at a stage temperature of 70° C. by a hand roller. Thus, a test piece having a thickness of approximately 1.0 mm was obtained. A change in viscosity resistance in a temperature range of 25 to 250° C. as heated at a rate of 5° C./min from 25° C. was measured for this test piece by using a rheometer (RS6000, manufactured by Haake). The melt viscosities at 70° C. and 120° C. (Pa·s) were respectively calculated from the obtained temperature-viscosity resistance curve.

### <To Evaluate Lamination Performance>

The film adhesive with a release film as obtained in each Example or Comparative Example was first bonded to one surface of a dummy silicon wafer (size: 8 inch, thickness: 50 μm) by using a manual laminator (trade name: FM-114, manufactured by Technovision, Inc.) at a temperature of 70° C. and a pressure of 0.1 MPa or 0.3 MPa. The presence or absence of voids at the interface between the film adhesive and the wafer after bonding was visually observed from the film adhesive side. Then, the lamination performance was evaluated based on the following criteria. Voids more easily occur in the bonding conditions at a pressure of 0.1 MPa than 0.3 MPa.

### —Evaluation Criteria—

AA: No voids are observed under a pressure of 0.1 MPa.
A: 1 or more voids are observed under a pressure of 0.1 MPa, but no voids are observed under a pressure of 0.3 MPa.
B: 1 to 4 voids are observed under a pressure of 0.3 MPa.
C: 5 or more voids are observed under a pressure of 0.3 MPa.

### <To Evaluate Wear Amount>

The film adhesive with a release film as obtained in each of Examples and Comparative Examples was first bonded to a dummy silicon wafer (size: 8 inch, thickness: 100 μm) by using a manual laminator (trade name: FM-114, manufactured by Technovision, Inc.) at a temperature of 70° C. and a pressure of 0.3 MPa. Thereafter, the release film was peeled off from the film adhesive. Then, a dicing film (trade name: K-13, manufactured by Furukawa Electric Co., Ltd.) and a dicing frame (trade name: DTF2-8-1H001, manufactured by DISCO Corporation) were bonded on a surface of the film adhesive opposite to the dummy silicon wafer, by using the same manual laminator at room temperature and a pressure of 0.3 MPa. Then, the material was diced to a size of 1.0 mm×1.0 mm under the processing conditions below by using a dicing apparatus (trade name: DFD-6340, manufactured by DISCO Corporation) equipped with two axes of dicing blades (Z1: NBC-ZH2030-SE (DD), manufactured by DISCO Corporation; Z2: NBC-ZH127F-SE (BB), manufactured by DISCO Corporation). This dicing step was repeated until the length of the film adhesive reached 150 m. Setup was performed before dicing (before processing) and at the point corresponding to the cutting distance of 150 m (after processing). The blade tip protrusion was measured by a non-contact type (laser type) method, and the blade wear amount after processing (blade tip protrusion before processing-blade tip protrusion after processing) was calculated. The calculated amount was evaluated according to the following evaluation criteria.

### —Processing Conditions—

Depth of cutting into dicing film: 30 μm
Cutting speed: 30 mm/sec
Rotation speed: 40000 rpm

### —Evaluation Criteria—

AA: Wear amount is less than 10 μm.
A: Wear amount is 10 μm or more and less than 20 μm.
B: Wear amount is 20 μm or more and less than 30 μm.
C: Wear amount is 30 μm or more.

### <To Evaluate Die Attachment>

The film adhesive with a release film as obtained in each of Examples and Comparative Examples was first bonded to one surface of a dummy silicon wafer (size: 8 inch, thickness: 100 μm) by using a manual laminator (trade name: FM-114, manufactured by Technovision, Inc.) at a temperature of 70° C. and a pressure of 0.3 MPa. Thereafter, the release film was peeled off from the film adhesive. Then, a dicing film (trade name: K-13, manufactured by Furukawa Electric Co., Ltd.) and a dicing frame (trade name: DTF2-8-1H001, manufactured by DISCO Corporation) were bonded on a surface of the film adhesive opposite to the dummy silicon wafer, by using the same manual laminator at room temperature and a pressure of 0.3 MPa. Then, dicing was performed, from the dummy silicon wafer side, to a dicing size of 10 mm×10 mm by using a dicing apparatus (trade name: DFD-6340, manufactured by DISCO Corporation) equipped with two axes of dicing blades (Z1: NBC-ZH2050 (27HEDD), manufactured by DISCO Corporation; Z2: NBC-ZH127F-SE (BC), manufactured by DISCO Corporation), thus obtaining a dummy chip.

Next, the dummy chip with a film adhesive was picked up from the dicing film by using a die bonder (trade name: DB-800, manufactured by Hitachi High-Tech Corporation). Then, the film adhesive side of the dummy chip with a film adhesive was thermocompression bonded to the mounting surface side of a lead frame substrate (42Alloy-based, manufactured by Toppan Printing Co., Ltd.) under conditions at a temperature of 120° C., a pressure of 0.05 MPa (load: 200 gf) or 0.1 MPa (load: 400 gf) for 1.0 seconds. Here, the mounting surface of the lead frame substrate is a metal surface having a slight surface roughness.

The presence or absence of voids at the interface between the film adhesive and the lead frame substrate was observed for the dummy chip with a film adhesive which had been thermocompression bonded on the substrate, by using an ultrasonic testing apparatus (SAT) (FS300III, manufactured by Hitachi Power Solutions Co., Ltd.). Then, the die attachment was evaluated based on the following criteria.

### —Evaluation Criteria—

AA: No voids are observed in all of the 24 semiconductor chips mounted at a pressure of 0.05 MPa.
A: Although the results do not fall under the above AA, no voids are observed in all of the 24 semiconductor chips mounted at a pressure of 0.1 MPa.
B: Although the results do not fall under the above AA or A, there are 1 to 3 chips in which voids are observed among the 24 semiconductor chips mounted at a pressure of 0.1 MPa.
C: Although the results do not fall under the above AA, A, or B, there are 4 or more chips in which voids are observed among the 24 semiconductor chips mounted at a pressure of 0.1 MPa.

### <To Evaluate Thermal Conductivity>

Squares whose one side was 50 mm or more were each cut out from the film adhesive with a release film as obtained in each of Examples and Comparative Examples. The squares in a state in which the release film had been peeled off were stacked to obtain a sample with a thickness of 5 mm.

This sample was placed on a disk-shaped mold with a diameter of 50 mm and a thickness 5 mm, heated at a temperature of 150° C. and a pressure of 2 MPa for 10 minutes using a compression press molding machine, and then taken out. Thereafter, the sample was further heated in a dryer at a temperature of 180° C. for one hour to thermally cure the film adhesive. Thus, a disk-shaped test piece having a diameter of 50 mm and a thickness of 5 mm was obtained.

The thermal conductivity (W/(m·K)) was measured for this test piece by using a thermal conductivity measurement apparatus (trade name: HC-110, manufacture by Eko Instruments Co., Ltd) according to the heat flow meter method (in accordance with JIS-A1412).

### <To Prepare Nitride Ceramic Filler>

The particle diameter and the like of the nitride ceramic filler used in each of Examples and Comparative Examples were controlled by subjecting the following nitride ceramic filler to the pulverization and deaggregation treatment under the following conditions.

### (Nitride Ceramic Filler)

AlN1: HF-01 (trade name), aluminum nitride, manufactured by Tokuyama Corporation
AlN2: A-01-F-WR2 (trade name), aluminum nitride, manufactured by MARUWA
AlN3: TFZ-A02P (trade name), aluminum nitride, manufactured by Toyo Aluminium K.K.
AlN4: H Grade (trade name), aluminum nitride, manufactured by Tokuyama Corporation
BN1: UHP-S1 (trade name), boron nitride filler, manufactured by Showa Denko K.K.

### (Pulverization and Deaggregation Treatment)

10 kg of each of the nitride ceramic fillers was charged into a table feeder (Model No: S-type, manufactured by Seishin Enterprise Co., Ltd.), and the pulverization and deaggregation treatment was performed using a jet mill pulverizer/crusher (Model No: FS-4 type, manufactured by Seishin Enterprise Co., Ltd.) at a treatment amount of 8.0 kg/hr and a nozzle pressure of 0.7 MPa.

The image analysis average particle diameter, the image analysis circularity, the image analysis maximum particle diameter, and the specific surface area of each of the nitride ceramic fillers before the pulverization and deaggregation treatment and after the pulverization and deaggregation treatment are collectively provided in the following Table 1.

TABLE 1

| | | Before pulverizationa and deaggregation | | | | After pulverization and deaggregation | | | |
|---|---|---|---|---|---|---|---|---|---|
| | | treatment (a) | | | | treatment (b) | | | |
| | | Image | | Image | | Image | | Image | |
| | | analysis | | analysis | | analysis | | analysis | |
| | | average | | maximum | Specific | average | | maximum | Specific |
| | | particle | Image | particle | surface | particle | Image | particle | surface |
| | Product | diameter | analysis | diameter | area | diameter | analysis | diameter | area |
| | name | (μm) | circularity | (μm) | (m²/g) | (μm) | circularity | (μm) | (m²/g) |
| AlN1 | HF-01 | 1.8 | 0.69 | 9.8 | 2.6 | 1.2 | 0.89 | 6.4 | 2.1 |
| AlN2 | A-01-F- | 2.1 | 0.68 | 10.5 | 2.8 | 1.4 | 0.80 | 8.6 | 1.9 |
| | WR2 | | | | | | | | |
| AlN3 | TFZ- | 3.5 | 0.66 | 13.2 | 3.4 | 2.5 | 0.83 | 8.9 | 1.7 |
| | A02P | | | | | | | | |
| AlN4 | H Grade | 1.9 | 0.7 | 11.2 | 2.6 | — | — | — | — |
| BN1 | UHP-S1 | 1.5 | 0.64 | 15.3 | 15 | 0.5 | 0.85 | 7.8 | 3.5 |

Hereinafter, for the sake of convenience, each of the nitride ceramic fillers before the pulverization and deaggregation treatment and each of the nitride ceramic fillers after the pulverization and deaggregation treatment are distinguished from each other by adding “a” and “b”, respectively, after the reference signs. For example, “AlN1” before the pulverization and deaggregation treatment is described as “AlN1a”, and “AlN1” after the pulverization and deaggregation treatment is described as “AlN1b”.

### EXAMPLES AND COMPARATIVE EXAMPLES

Adhesive compositions and film adhesives of Examples and Comparative Examples were obtained as follows.

### Example 1

In a 1000-ml separable flask, 55.5 parts by mass of cresol novolac type epoxy resin (trade name: EOCN-104S; weight average molecular weight: 5000; softening point: 92° C.; solid; epoxy equivalent amount: 218 g/eq; manufactured by Nippon Kayaku Co., Ltd.), 48.5 parts by mass of bisphenol A type epoxy resin (trade name: YD-128; weight average molecular weight: 400; softening point: less than 25° C.; liquid; epoxy equivalent amount: 190 g/eq; manufactured by NSCC Epoxy Manufacturing Co., Ltd.), and 120 parts by mass of polyurethane resin solution (trade name: Dynaleo VA-9310M; weight average molecular weight: 120000; Tg: 39° C.; solvent: MEK/IPA mixed solvent; manufactured by TOYOCHEM CO., LTD.) (30 parts by mass as a polyurethane resin) were heated with stirring at 110° C. for 2 hours, to prepare a resin varnish.

Subsequently, the resin varnish was transferred to an 800-ml planetary mixer, and 252 parts by mass of AlN1b as a nitride ceramic filler (HF-01 after pulverization and deaggregation treatment) was introduced to the mixer. Further, 2.0 parts by mass of epoxy resin curing agent (trade name: 2PHZ-PW; an imidazole type curing agent; manufactured by Shikoku Chemicals Corporation) and 3.0 parts by mass of silane coupling agent (trade name: S-510; manufactured by JNC Corporation) were introduced to the mixer. The contents were then mixed with stirring for 1 hour at room temperature. Then, defoaming under vacuum was conducted, thus obtaining a mixed varnish (adhesive composition).

Next, the obtained mixed varnish was applied onto a release-treated PET film (release film) having a thickness of 38 μm and then dried by heating at 130° C. for 10 minutes to form a film adhesive having a length of 300 mm, a width of 200 mm, and a thickness of 10 μm. In this way, a film adhesive with a release film was obtained.

### Example 2

An adhesive composition and a film adhesive with a release film of Example 2 were obtained in the same manner as in Example 1 except that 120 parts by mass of an acrylic polymer solution (trade name: S-2060; weight average molecular weight: 500000; Tg: −23° C.; solid content: 25% (organic solvent: toluene); manufactured by TOAGOSEI CO., LTD.) (30 parts by mass as an acrylic resin) was used instead of the polyurethane resin solution in Example 1.

### Example 3

An adhesive composition and a film adhesive with a release film of Example 3 were obtained in the same manner as in Example 1 except that 85 parts by mass of a bisphenol A type phenoxy resin solution (trade name: YP-50EK35; weight average molecular weight: 70000; Tg: 84° C.; solid content: 35% (organic solvent: MEK); manufactured by Nippon Steel Epoxy Manufacturing Co., Ltd.) (30 parts by mass as a phenoxy resin) was used instead of the polyurethane resin solution in Example 1.

### Example 4

An adhesive composition and a film adhesive with a release film of Example 4 were obtained in the same manner as in Example 1 except that 700 parts by mass of AlN1b (HF-01 after pulverization and deaggregation treatment) was used in Example 1.

### Example 5

An adhesive composition and a film adhesive with a release film of Example 5 were obtained in the same manner as in Example 1 except that 126 parts by mass of AlN1b (HF-01 after pulverization and deaggregation treatment) was used in Example 1.

### Example 6

An adhesive composition and a film adhesive with a release film of Example 6 were obtained in the same manner as in Example 1 except that 252 parts by mass of AlN2b (A-01-F-WR2 after pulverization and deaggregation treatment) was used instead of AlN1b in Example 1.

### Example 7

An adhesive composition and a film adhesive with a release film of Example 7 were obtained in the same manner as in Example 1 except that 252 parts by mass of AlN3b (TFZ-A02P after pulverization and deaggregation treatment) was used instead of AlN1b in Example 1.

### Example 8

An adhesive composition and a film adhesive with a release film of Example 8 were obtained in the same manner as in Example 1 except that 178 parts by mass of BN1b (UHP-S1 after pulverization and deaggregation treatment) was used instead of AlN1b in Example 1.

### Comparative Example 1

An adhesive composition and a film adhesive with a release film of Comparative Example 1 were obtained in the same manner as in Example 1 except that 252 parts by mass of AlN1a (HF-01 before pulverization and deaggregation treatment) was used instead of AlN1b in Example 1.

### Comparative Example 2

An adhesive composition and a film adhesive with a release film of Comparative Example 2 were obtained in the same manner as in Example 1 except that 880 parts by mass of AlN1b (HF-01 after pulverization and deaggregation treatment) was used in Example 1.

### Comparative Example 3

An adhesive composition and a film adhesive with a release film of Comparative Example 3 were obtained in the same manner as in Example 1 except that 95 parts by mass of AlN1b (HF-01 subjected to pulverization and deaggregation treatment) was used in Example 1.

### Comparative Example 4

An adhesive composition and a film adhesive with a release film of Comparative Example 4 were obtained in the same manner as in Example 6 except that 252 parts by mass of AlN2a (A-01-F-WR2 before pulverization and deaggregation treatment) was used instead of AlN2b in Example 6.

### Comparative Example 5

An adhesive composition and a film adhesive with a release film of Comparative Example 5 were obtained in the same manner as in Example 7 except that 252 parts by mass of AlN3a (TFZ-A02P before pulverization and deaggregation treatment) was used instead of AlN3b in Example 7.

### Comparative Example 6

An adhesive composition and a film adhesive with a release film of Comparative Example 6 were obtained in the same manner as in Example 8 except that 178 parts by mass of BN1a (UHP-S1 before pulverization and deaggregation treatment) was used instead of BN1b in Example 8.

### Comparative Example 7

An adhesive composition and a film adhesive with a release film of Comparative Example 7 were obtained in the same manner as in Example 1 except that 335 parts by mass of AlN4a (H Grade before pulverization and deaggregation treatment) was used instead of AlN1b in Example 1.

The obtained film adhesive with a release film was subjected to melt viscosity measurement, lamination performance evaluation, wear amount evaluation, die attachment evaluation, and thermal conductivity evaluation as described above.

The obtained results are summarized and shown in Table 2 together with the compositions of the adhesive composition and the film adhesive.

TABLE 2

| | | | Ex. | | | | | | | |
|---|---|---|---|---|---|---|---|---|---|---|
| | | | 1 | 2 | 3 | 4 | 5 | 6 | 7 | 8 |
| Film | Epoxy resin | EOCN-104S (cresol novolac type epoxy | 55.5 | 55.5 | 55.5 | 55.5 | 55.5 | 55.5 | 55.5 | 55.5 |
| adhesive | | resin) | | | | | | | | |
| composition | | YD-128 (liquid bisphenol A-type epoxy | 48.5 | 48.5 | 48.5 | 48.5 | 48.5 | 48.5 | 48.5 | 48.5 |
| [parts by | | resin) | | | | | | | | |
| mass] | Polymer | VA-9310MF (urethane resin) | 30 | | | 30 | 30 | 30 | 30 | 30 |
| | component | S-2060 (acrylic resin) | | 30 | | | | | | |
| | | YP-50 (bisphenol A type phenoxy resin) | | | 30 | | | | | |
| | Nitride | AIN1b (HF-01 after pulverization and | 252 | 252 | 252 | 700 | 126 | | | |
| | ceramic filler | deaggregation treatment) | | | | | | | | |
| | | AIN2b (A-01-F-WR2 after pulverization | | | | | | 252 | | |
| | | and deaggregation treatment) | | | | | | | | |
| | | AIN3b (TFZ-A02P after pulverization and | | | | | | | 252 | |
| | | deaggregation treatment) | | | | | | | | |
| | | BN1b (UHP-S1 after pulverization and | | | | | | | | 178 |
| | | deaggregation treatment) | | | | | | | | |
| | Epoxy resin | 2PHZ-PW (imidazole-type curing agent) | 2 | 2 | 2 | 2 | 2 | 2 | 2 | 2 |
| | curing agent | | | | | | | | | |

| | | | | | | | | |
|---|---|---|---|---|---|---|---|---|
| S-510 (epoxysilane coupling agent) | 3 | 3 | 3 | 3 | 3 | 3 | 3 | 3 |
| Total solid content | 391 | 391 | 391 | 839 | 265 | 391 | 391 | 317 |
| Epoxy resin content | 27 | 27 | 27 | 12 | 39 | 27 | 27 | 33 |
| Nitride ceramic filler packing amount (vol %) | 40.0 | 40.0 | 40.0 | 65.0 | 25.0 | 40.0 | 40.0 | 40.0 |

| | | | | | | | | |
|---|---|---|---|---|---|---|---|---|
| Melt viscosity at 70° C. (Pa · s) | 26000 | 35000 | 23000 | 49500 | 16500 | 25000 | 23500 | 38000 |
| Melt viscosity at 120° C. (Pa · s) | 2200 | 2600 | 2500 | 10000 | 650 | 2000 | 1800 | 4500 |
| Lamination performance evaluation | AA | AA | AA | A | AA | AA | AA | A |
| Wear amount evaluation | AA | AA | AA | A | AA | AA | AA | AA |
| Die attachment evaluation | AA | AA | AA | A | AA | AA | AA | AA |
| Thermal conductivity (W/m · K) | 2.1 | 2.0 | 2.0 | 4.5 | 1.0 | 2.2 | 2.8 | 1.1 |

| | | | CEx. | | | | | | |
|---|---|---|---|---|---|---|---|---|---|
| | | | 1 | 2 | 3 | 4 | 5 | 6 | 7 |
| Film | Epoxy resin | EOCN-104S (cresol novolac type epoxy | 55.5 | 55.5 | 55.5 | 55.5 | 55.5 | 55.5 | 55.5 |
| adhesive | | resin) | | | | | | | |
| composition | | YD-128 (liquid bisphenol A-type epoxy | 48.5 | 48.5 | 48.5 | 48.5 | 48.5 | 48.5 | 48.5 |
| [parts by | | resin) | | | | | | | |
| mass] | Polymer | VA-9310MF (urethane resin) | 30 | 30 | 30 | 30 | 30 | 30 | 30 |
| | component | | | | | | | | |
| | Nitride | AlN1a (HF-01 before pulverization and | 252 | | | | | | |
| | ceramic filler | deaggregation treatment) | | | | | | | |
| | | AlN1b (HF-01 after pulverization and | | 880 | 95 | | | | |
| | | deaggregation treatment) | | | | | | | |
| | | AlN2a (A-01-F-WR2 before pulverization | | | | 252 | | | |
| | | deaggregation treatment) | | | | | | | |
| | | AlN3a (TFZ-A02P before pulverization | | | | | 252 | | |
| | | and deaggregation treatment) | | | | | | | |
| | | BN1a (UHP-S1 before pulverization and | | | | | | 178 | |
| | | deaggregation treatment) | | | | | | | |
| | | AlN4a (H Grade before pulverization and | | | | | | | 335 |
| | | deaggregation treatment) | | | | | | | |
| | Epoxy resin | 2PHZ-PW (imidazole-type curing agent) | 2 | 2 | 2 | 2 | 2 | 2 | 2 |
| | curing agent | | | | | | | | |

| | | | | | | | |
|---|---|---|---|---|---|---|---|
| S-510 (epoxysilane coupling agent) | 3 | 3 | 3 | 3 | 3 | 3 | 3 |
| Total solid content | 391 | 1019 | 234 | 391 | 391 | 317 | 474 |
| Epoxy resin content | 27 | 10 | 45 | 27 | 27 | 33 | 22 |
| Nitride ceramic filler packing amount (vol %) | 40.0 | 70.0 | 20.0 | 40.0 | 40.0 | 40.0 | 47.0 |

| | | | | | | | |
|---|---|---|---|---|---|---|---|
| Melt viscosity at 70° C. (Pa · s) | 29000 | 52000 | 15000 | 27500 | 25500 | 58000 | 20000 |
| Melt viscosity at 120° C. (Pa · s) | 2450 | 12000 | 400 | 2300 | 2200 | 10500 | 3560 |
| Lamination performance evaluation | B | B | AA | B | B | C | B |
| Wear amount evaluation | A | A | AA | A | B | AA | A |
| Die attachment evaluation | B | B | AA | B | B | C | C |
| Thermal conductivity (W/m · K) | 2.2 | 4.8 | 0.8 | 2.1 | 2.7 | 1.3 | 1.9 |

Remarks: ‘Ex.’ means Example according to this invention.
Remarks: ‘CEx.’ means Comparative Example.

### Notes in Table

Blanks in the rows of “Polymer component” and “Nitride ceramic filler” mean that the component is not contained.

The “Total solid content” is the total amount (parts by mass) of the epoxy resin, the polymer component, the nitride ceramic filler, the epoxy resin curing agent, and the silane coupling agent.

The “Epoxy resin content” is the content (parts by mass) of the epoxy resin in 100 parts by mass of the total content of the components constituting the film adhesive (epoxy resin, polymer component, nitride ceramic filler, epoxy resin curing agent, silane coupling agent).

The “nitride ceramic filler packing amount (vol %)” is a proportion (vol %) of the nitride ceramic filler in the total content of the epoxy resin, the epoxy resin curing agent, the polymer component, and the nitride ceramic filler.

The following is clear from Table 2 above.

In the adhesive compositions of Comparative Examples 1 and 4 to 7, a nitride ceramic filler that does not satisfy at least one of the conditions (1) to (3) is used. In all of the 10 μm-thick film adhesives obtained from these adhesive compositions, voids were observed during bonding to a wafer under a pressure of 0.3 MPa (lamination step) and during bonding to a lead frame substrate under a pressure of 0.1 MPa (die attachment step). It is considered that coarse particles were contained in the nitride ceramic filler, or a void was formed due to generation of an aggregate. In Comparative Example 5, the wear amount of the processing blade was 20 μm or more. It is considered that wear of the processing blade was severe because the nitride ceramic filler that did not satisfy all of the conditions (1) to (3) was used.

In Comparative Examples 2 and 3, the nitride ceramic filler satisfying the conditions (1) to (3) is used, but the content thereof does not satisfy 25 to 65 vol %. For the film adhesive obtained from the adhesive composition of Comparative Example 2, voids were observed during bonding to a wafer under a pressure of 0.3 MPa (lamination step) and during bonding to a lead frame substrate under a pressure of 0.1 MPa (die attachment step). It is considered that the increase in the melt viscosity made the generation of voids more likely. The film adhesive obtained from the adhesive composition of Comparative Example 3 had a low thermal conductivity of 0.8 W/m·K and was thus poor in thermal conductivity. It is considered that the packing amount of the nitride ceramic filler was too small.

By contrast, in the adhesive compositions of Examples 1 to 8, a nitride ceramic filler that satisfies all of the conditions (1) to (3) is used. In any of the 10 μm-thick film adhesives obtained from these adhesive compositions, no voids were observed during bonding to a wafer under a pressure of 0.3 MPa (lamination step) and during bonding to a lead frame substrate under a pressure of 0.1 MPa (die attachment step). In addition, all the cured products exhibited excellent thermal conductivity of 1.0 W/m·K or more, and the wear amount of the processing blade was able to be suppressed to less than 20 μm. As described above, it can be seen that according to the adhesive composition of the present invention, generation of voids is suppressed both at the time of lamination on a wafer and at the time of die attachment even as a form of a thin film, excellent thermal conductivity is exhibited, and wear of a processing blade can also be suppressed.

In particular, it is found that voids can be further suppressed when the melt viscosity at 70° C. is in the range of 16000 to 36000 Pa·s or when the melt viscosity at 120° C. is in the range of 1500 to 3000 Pa·s.

Having described the present invention as related to the embodiment, it is our intention that the present invention not be limited by any of the details of the description, unless otherwise specified, but rather be construed broadly within its spirit and scope as set out in the accompanying claims.

The present application claims priority of Patent Application No. 2023-029805, filed in Japan on Feb. 28, 2023, which is herein incorporated by reference as part of the present specification.

### DESCRIPTION OF SYMBOLS

1 Semiconductor wafer
2 Film adhesive
3 Dicing film
4 Semiconductor chip
5 Semiconductor chip with adhesive layer
6 Circuit board
7 Bonding wire
8 Sealing resin
9 Semiconductor package

1. A thermally conductive adhesive composition comprising an epoxy resin (A), an epoxy resin curing agent (B), a polymer component (C), and a nitride ceramic filler (D),
wherein the nitride ceramic filler (D) satisfies the following conditions (1) to (3), and
wherein a proportion of the nitride ceramic filler (D) in a total content of the epoxy resin (A), the epoxy resin curing agent (B), the polymer component (C), and the nitride ceramic filler (D) is 25 to 65% by volume:
(1) an image analysis average particle diameter is 0.1 to 2.5 μm;
(2) an image analysis circularity is 0.7 or more; and
(3) an image analysis maximum particle diameter is 10.0 μm or less.

2. The thermally conductive adhesive composition according to claim 1, wherein when a film adhesive formed using the adhesive composition is heated at a rate of 5° C./min from 25° C., a melt viscosity at 70° C. is 15000 to 50000 Pa·s.

3. The thermally conductive adhesive composition according to claim 1, wherein when a film adhesive formed using the adhesive composition is heated at a rate of 5° C./min from 25° C., a melt viscosity at 120° C. is 500 to 10000 Pa·s.

4. The thermally conductive adhesive composition according to claim 1, wherein a film adhesive formed using the adhesive composition gives a cured product having a thermal conductivity of 1.0 W/m·K or more after thermal curing.

5. The thermally conductive adhesive composition according to claim 1, wherein the nitride ceramic filler (D) is a pulverized and deaggregated product.

6. A method of producing the thermally conductive adhesive composition according to claim 1, the method comprising subjecting a nitride ceramic filler to a pulverization and deaggregation treatment to prepare the nitride ceramic filler as the nitride ceramic filler (D) satisfying the above conditions (1) to (3), and obtaining the thermally conductive adhesive composition using the nitride ceramic filler (D).

7. A thermally conductive film adhesive obtained from the thermally conductive film adhesive composition according to claim 1.

8. The thermally conductive film adhesive according to claim 7, having a thickness of 1 to 10 μm.

9. A dicing die attach film obtained by laminating a dicing film and the thermally conductive film adhesive according to claim 7.

10. A semiconductor package wherein a semiconductor chip and a circuit board, or semiconductor chips are bonded with a thermally cured product of the thermally conductive film adhesive according to claim 7.

11. A method of producing a semiconductor package, comprising:
a first step of providing an adhesive layer by thermocompression bonding the thermally conductive film adhesive according to claim 7 to a back surface of a semiconductor wafer in which at least one semiconductor circuit is formed on a surface, and providing a dicing film via the adhesive layer;
a second step of integrally dicing the semiconductor wafer and the adhesive layer to obtain a semiconductor chip with an adhesive layer, which includes the semiconductor chip and a piece of the adhesive, on the dicing film;
a third step of separating the semiconductor chip with an adhesive layer from the dicing film and thermocompression bonding the semiconductor chip with an adhesive layer and a circuit board via the adhesive piece; and
a fourth step of thermally curing the adhesive layer.

12. The method of producing a semiconductor package according to claim 11, wherein the first step is a step of thermocompression-bonding the dicing die attach film according to claim 9 to a back surface of the semiconductor wafer.
